(19) United States
(12) Patent Application Publication
(10) Pub. No.: US 2025/0204043 A1
(43) Pub. Date: Jun. 19, 2025

(54) DISPLAY DEVICE

(71) Applicant: Sharp Display Technology Corporation, Kameyama City, Mie (JP)

(72) Inventor: Izumi ISHIDA, Kameyama City, Mie (JP)

(21) Appl. No.: 18/846,808

(22) PCT Filed: May 9, 2022
(86) PCT No.: PCT/JP2022/019632

§ 371 Date: Sep. 13, 2024

(51) Int. Cl. H10D 86/40; H10D 86/60

(52) U.S. Cl. CPC H10D 86/423; H10D 86/60

(57) ABSTRACT

A display device includes: an oxide semiconductor film; an interlayer insulating film in contact with the oxide semiconductor film; and a pixel circuit board including an effective circuit region group configured to contribute to a display, wherein the pixel circuit board has a first effective circuit region located on an outermost periphery of the effective circuit region group and including the oxide semiconductor film, the first effective circuit region has a contact hole extending through the interlayer insulating film, and a through hole extending through the interlayer insulating film is provided adjacent to the first effective circuit region outside the effective circuit region group.

### TECHNICAL FIELD

The present disclosure relates to display devices.

### BACKGROUND ART

Patent Literature 1 discloses a transistor containing an oxide semiconductor in its channel.

### CITATION LIST

Patent Literature

Patent Literature 1: Japanese Unexamined Patent Application Publication No. 2016-100521 (Publication Date: May 30, 2016)

### SUMMARY

### Technical Problem

Using a transistor containing an oxide semiconductor in its channel in a display device disadvantageously decreases the display quality of the display device in a prescribed location.

### Solution to Problem

The present disclosure, in one aspect thereof, is directed to a display device including: an oxide semiconductor film; an interlayer insulating film in contact with the oxide semiconductor film; and a pixel circuit board including an effective circuit region group configured to contribute to a display, wherein the pixel circuit board has a first effective circuit region located on an outermost periphery of the effective circuit region group and including the oxide semiconductor film, the first effective circuit region has a contact hole extending through the interlayer insulating film, and a through hole extending through the interlayer insulating film is provided adjacent to the first effective circuit region outside the effective circuit region group.

### Advantageous Effects of Disclosure

The present disclosure, in one aspect thereof, can increase the display quality of the display device.

### BRIEF DESCRIPTION OF DRAWINGS

FIG. 1 is a plan view of an exemplary structure of a display device in accordance with Embodiment 1.

FIG. 2 is a cross-sectional view taken along line A-B-C-D in FIG. 1.

FIG. 3 is a cross-sectional view taken along line A′-B′-C′-D′ in FIG. 1.

FIG. 4 is a plan view of an exemplary structure of a pixel circuit board.

FIG. 5 is a circuit diagram of an exemplary structure of a first effective circuit region.

FIG. 6 is a cross-sectional view of the first effective circuit region.

FIG. 7 is a cross-sectional view of a first dummy circuit region.

FIG. 8 is a cross-sectional view of the first effective circuit region.

FIG. 9 is a cross-sectional view of the first dummy circuit region.

FIG. 10 is a cross-sectional view of the first effective circuit region.

FIG. 11 is a cross-sectional view of the first dummy circuit region.

FIG. 12 a cross-sectional view of the first effective circuit region.

FIG. 13 a cross-sectional view of the first dummy circuit region.

FIG. 14 is a plan view of an exemplary structure of a pixel circuit board in accordance with Embodiment 2.

FIG. 15 is a plan view of another exemplary structure of the pixel circuit board in accordance with Embodiment 2.

FIG. 16 is a schematic illustration of an exemplary structure of a display device in accordance with Embodiment 3.

### DESCRIPTION OF EMBODIMENTS

### Embodiment 1

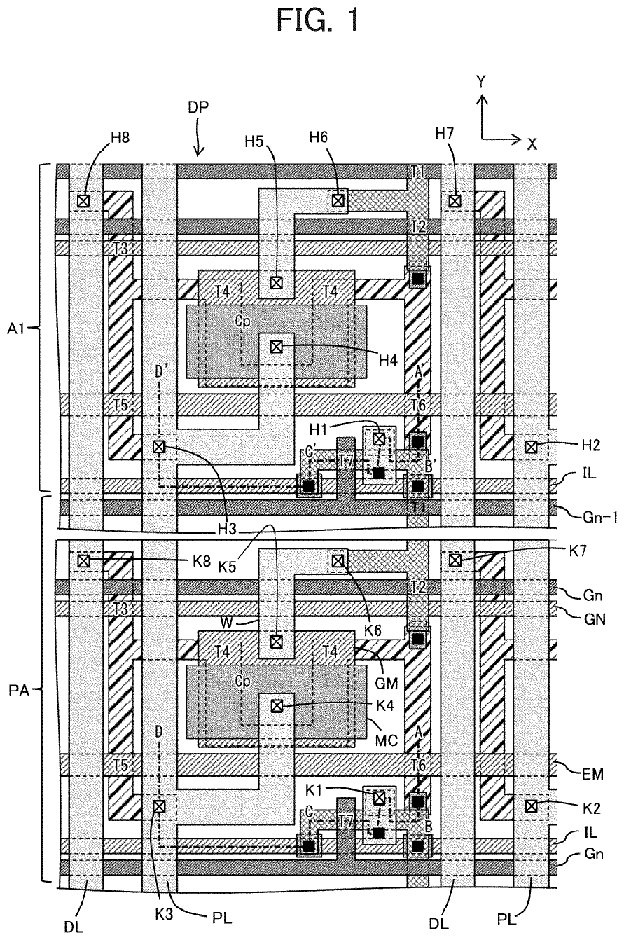

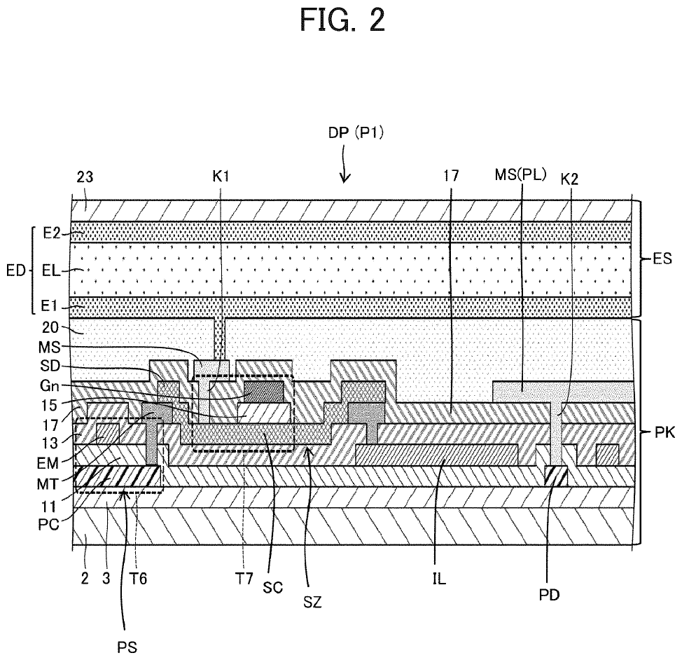

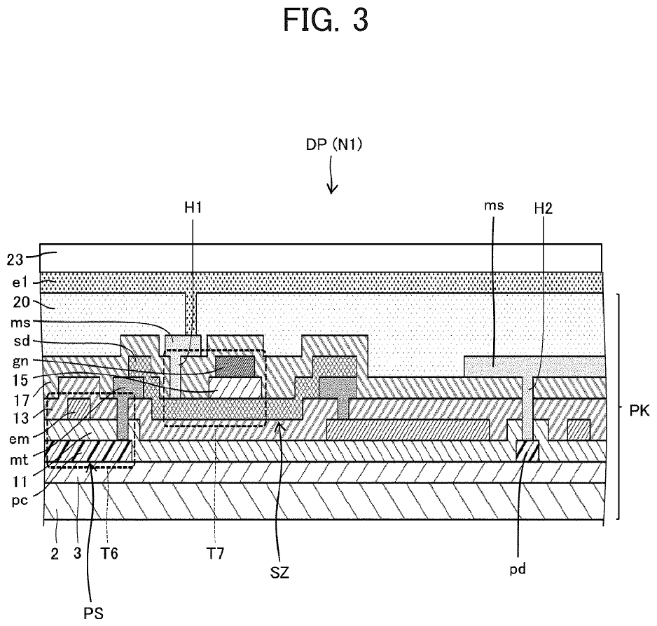

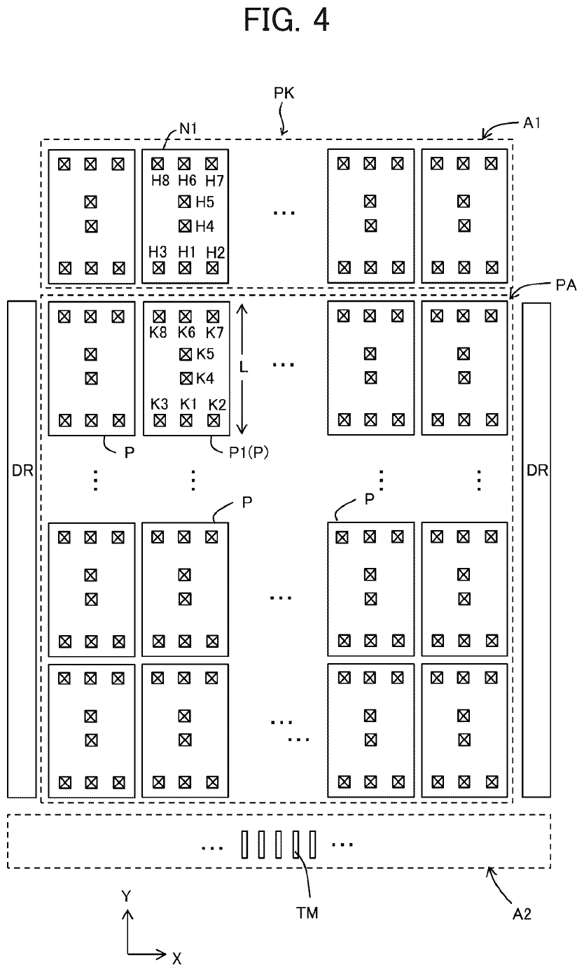

FIG. 1 is a plan view of an exemplary structure of a display device in accordance with Embodiment 1. FIG. 2 is a cross-sectional view taken along line A-B-C-D in FIG. 1. FIG. 3 is a cross-sectional view taken along line A′-B′-C′-D′in FIG. 1. FIG. 4 is a plan view of an exemplary structure of a pixel circuit board in accordance with Embodiment 1.

Referring to FIGS. 1 to 4, a display device DP includes an oxide semiconductor film SZ and an interlayer insulating film 17 provided in contact with the oxide semiconductor film SZ and includes a pixel circuit board PK in which an effective circuit region group PA is formed that contributes to producing a display. The pixel circuit board PK includes a first effective circuit region P1 positioned on the outermost periphery of the effective circuit region group PA and containing the oxide semiconductor film SZ. The first effective circuit region P1 has a contact hole K1 through the interlayer insulating film 17. A through hole H1 is provided through the interlayer insulating film 17 outside the effective circuit region group PA (in a non-effective area) and adjacent to the first effective circuit region P1.

The pixel circuit board PK has the through hole H1 through the interlayer insulating film 17 and adjacent to the first effective circuit region P1. Therefore, the hydrogen atoms drawn in, for example, in the formation of the interlayer insulating film 17 containing elemental silicon can dissipate through the through hole H1, and the diffusion of hydrogen atoms into the oxide semiconductor film SZ (especially, into a channel portion) can be restrained in the first effective circuit region P1. This particular structure can hence ensure the channel properties of the oxide semiconductor film SZ, thereby enhancing display quality.

The through hole H1 and the first effective circuit region P1 may be adjacent to each other in a first direction (Y-direction) so that the distance in the first direction between the first effective circuit region P1 and the through hole H1 can be smaller than a dimension L of the first effective circuit region P1 in the first direction.

The interlayer insulating film 17 may be provided on or above the oxide semiconductor film SZ and contain silicon as a component element. The first effective circuit region P1 may include an oxide semiconductor transistor (e.g., T1) with a part of the oxide semiconductor film SZ as its channel as shown in FIG. 1. The first effective circuit region P1 may include a silicon-based transistor with a channel containing, for example, polysilicon. The oxide semiconductor transistor (e.g., T1) may be located closer to the through hole H1 than to the silicon-based transistor (e.g., drive transistor T4). The interlayer insulating film 17 may contain H (hydrogen) as an impurity element.

Referring to FIG. 4, the pixel circuit board PK has a first edge region A1 in which the through hole H1 is formed. A first dummy circuit region N1 that does not contribute to producing a display may be provided adjacent to the first effective circuit region P1 outside the effective circuit region group PA so that the first dummy circuit region N1 can include the through hole H1. The circuit configuration in the first effective circuit region P1 may be the same as the circuit configuration in the first dummy circuit region N1.

Referring to FIGS. 1 to 3, the display device DP may include: an undercoat film 3; a silicon semiconductor film SP; a first gate insulating film 11; a first scan signal line GN, a light-emission control line EM, and an initialize signal line IL; an inorganic insulating film 13; a metal film MT; the oxide semiconductor film SZ; a second gate insulating film 15; a second scan signal line Gn; the interlayer insulating film 17; an overlying wire MS; an organic insulating film 20; and a light-emitting element layer ES, all of which are provided on a main substrate 2 in this order. The metal film MT includes a capacitor electrode MC. The overlying wire MS includes a power supply line PL, a data signal line DL, and a relay line W. The light-emitting element layer ES may include: a light-emitting element ED including an anode E1, a cathode E2, and an EL layer; and a sealing layer 23.

The oxide semiconductor film SZ includes a channel portion (semiconductor portion) SC and a conductor portion SD. The conductor portion SD can be formed by, for example, reducing the semiconductor portion or doping the semiconductor portion. A silicon semiconductor film PS includes a channel portion (semiconductor portion) PC and a conductor portion PD. The conductor portion PD can be formed by doping the semiconductor portion.

The contact hole K1 in the first effective circuit region P1 may connect the conductor portion SD in the oxide semiconductor film SZ to the overlying wire MS located on or above the interlayer insulating film 17. The pixel circuit board PK may include a dummy conductor portion sd in the same layer as the conductor portion SD and in contact with a bottom face for the through hole H1. The pixel circuit board PK may include a dummy overlying wire ms in the same layer as the overlying wire MS and in contact with a top face for the through hole H1.

The effective circuit region group PA may include a matrix of effective circuit regions P including the first effective circuit region P1. Each of the plurality of effective circuit regions P may be rectangular. The pixel circuit board PK may have a second edge region A2 including a plurality of terminals TM. The effective circuit region group PA may be located between the first edge region A1 and the second edge region A2.

Letting a second direction (X-direction) be a direction perpendicular to the first direction, the pixel circuit board PK may have a drive circuit region DR adjacent to the effective circuit region group PA in the second direction. The effective circuit region group PA may be flanked by two drive circuit regions DR.

The pixel circuit board PK may include the data signal line DL extending in the first direction (Y-direction). The display device DP may include the light-emitting element layer ES containing: the anode E1, the cathode E2, and a light-emitting layer EL between the anode E1 and the cathode E2.

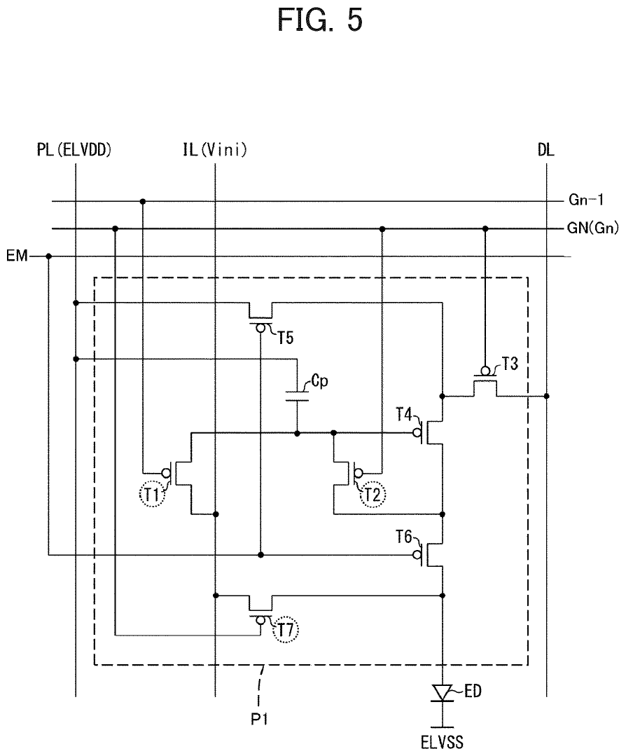

FIG. 5 is a circuit diagram of an exemplary structure of the first effective circuit region. Referring to FIG. 5, the first effective circuit region P1 may include a transistor T1 serving as a resetting transistor, a transistor T2 serving as a threshold-compensation transistor, a transistor T3 serving as a write transistor, a transistor T4 serving as a drive transistor, a transistor T5 serving as a power supply transistor, a transistor T6 serving as a light-emission control transistor, and a transistor T7 serving as an initialization transistor.

The transistors T1, T2, and T7 may be oxide semiconductor transistors that have the channel portion SC. The transistors T3, T4, T5, and T6 may be silicon-based transistors that have the channel portion PC.

The transistor T3 has its gate terminal connected to the first scan signal line GN of the current stage. Each of the transistors T2 and T7 has its gate terminal connected to the second scan signal line Gn of the current stage. The transistor T1 has its gate terminal connected to the second scan signal line Gn−1 of the preceding stage. The transistor T6 has its gate terminal connected to the light-emission control line EM. The transistor T3 has its source terminal connected to the data signal line DL. The transistor T5 has its source terminal connected to the power supply line PL which is fed with a high potential power supply (ELVDD). The transistor T4 has its gate terminal connected to the power supply line PL via a capacitor Cp. The capacitor Cp contains a gate metal GM.

The first effective circuit region P1 may include a polysilicon transistor (e.g., T4) as a drive transistor for controlling current between the anode E1 and the cathode E2. The pixel circuit board PK may include the initialize signal line IL. An oxide semiconductor transistor (e.g., T1) may be electrically connected to the control terminal (gate terminal) of the polysilicon transistor (e.g., T4) and to the initialize signal line IL.

The oxide semiconductor film SZ contains a reducing type of oxide semiconductor of which the conductivity is improved by reduction. The oxide semiconductor film SZ contains, for example, an oxide including at least one of indium (In), gallium (Ga), and zinc (Zn). The oxide semiconductor film SZ may contain an indium gallium zinc oxide (InGaZnO). The interlayer insulating film 17 may contain at least one of silicon oxide (SiOx), silicon nitride (SiNx), and silicon oxynitride (SiNOx). Silicon oxide (SiO) can be prepared by vapor phase epitaxy from a gaseous mixture containing silane (SiH4) and oxygen (O2). Silicon nitride (SiN) can be prepared from a gaseous mixture containing silane (SiH₄), ammonia (NH₃), and nitrogen (N₂). Silicon oxynitride can be prepared from a gaseous mixture containing silane (SiH₄), ammonia (NH₃), oxygen (O₂), and nitrogen (N₂). Therefore, silicon oxide (SiOx), silicon nitride (SiNx), and silicon oxynitride all contain hydrogen (H) as an impurity element.

Referring to FIG. 2, the first effective circuit region P1 may have a contact hole K2 through the first gate insulating film 11, the inorganic insulating film 13, and the interlayer insulating film 17 to electrically connect the conductor portion PD to the overlying wire MS (power supply line PL). Referring to FIG. 3, the first dummy circuit region N1 may have a through hole H2 through the first gate insulating film 11, the inorganic insulating film 13, and the interlayer insulating film 17 to electrically connect a dummy conductor portion pd (in the same layer as PD) to the dummy overlying wire ms (in the same layer as MS).

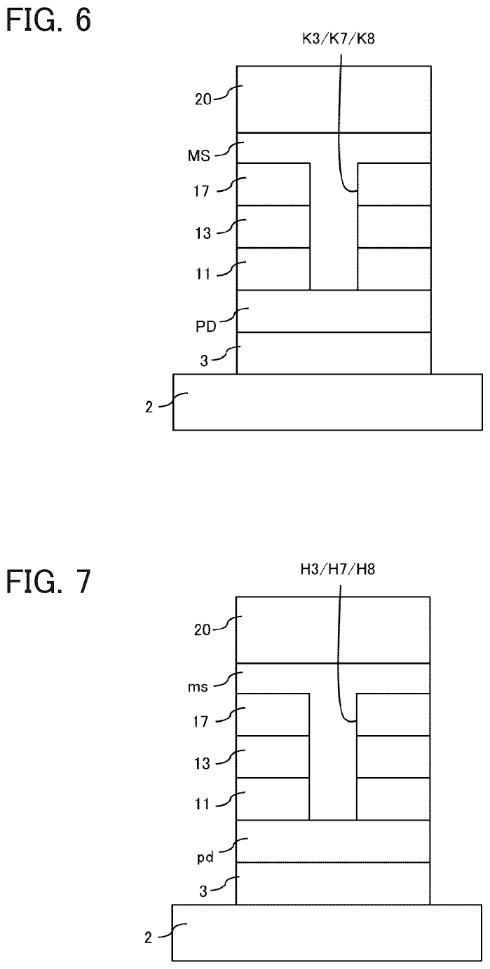

FIG. 6 is a cross-sectional view of the first effective circuit region. FIG. 7 is a cross-sectional view of the first dummy circuit region. Referring to FIG. 6, the first effective circuit region P1 may have contact holes K3, K7, and K8 each extending through the first gate insulating film 11, the inorganic insulating film 13, and the interlayer insulating film 17 to electrically connect the conductor portion PD to the overlying wire MS. Referring to FIG. 7, the first dummy circuit region Nl may have through holes H3, H7, and H8 each extending through the first gate insulating film 11, the inorganic insulating film 13, and the interlayer insulating film 17 to electrically connect the dummy conductor portion pd to the dummy overlying wire ms.

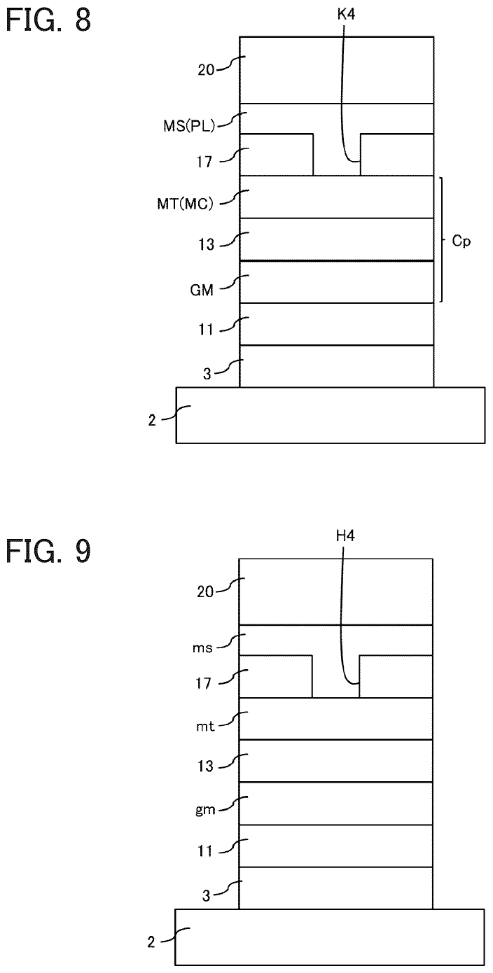

FIG. 8 is a cross-sectional view of the first effective circuit region. FIG. 9 is a cross-sectional view of the first dummy circuit region. Referring to FIG. 8, the first effective circuit region P1 may have a contact hole K4 extending through the interlayer insulating film 17 to electrically connect the metal film MT (capacitor electrode MC) to the overlying wire MS (power supply line PL). Referring to FIG. 9, the first dummy circuit region N1 may have a through hole H4 extending through the interlayer insulating film 17 to electrically connect a dummy metal film mt (in the same layer as MT) to the dummy overlying wire ms.

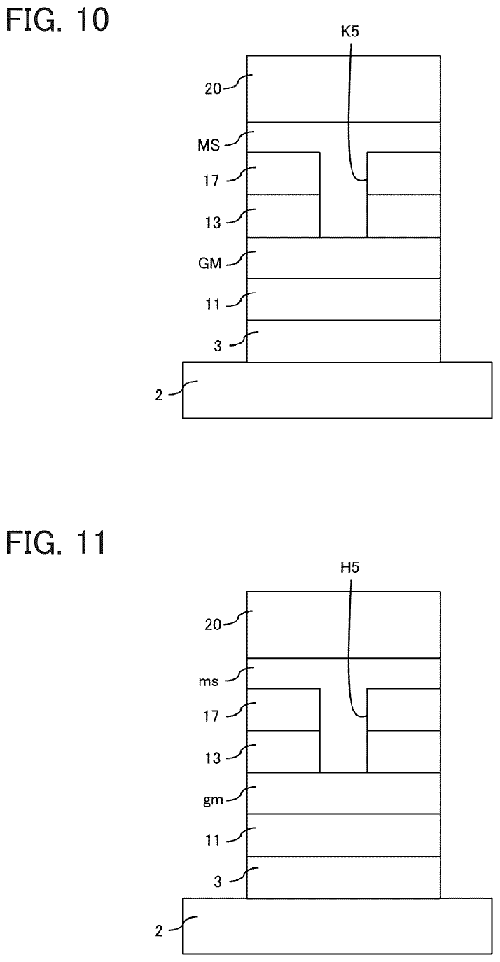

FIG. 10 is a cross-sectional view of the first effective circuit region. FIG. 11 is a cross-sectional view of the first dummy circuit region. Referring to FIG. 10, the first effective circuit region P1 may have a contact hole K5 extending through the inorganic insulating film 13 and the interlayer insulating film 17 to electrically connect the gate metal GM to the overlying wire MS (relay line W). Referring to FIG. 11, the first dummy circuit region N1 may have a through hole H5 extending through the inorganic insulating film 13 and the interlayer insulating film 17 to electrically connect a dummy gate metal gm (in the same layer as GM) to the dummy overlying wire ms.

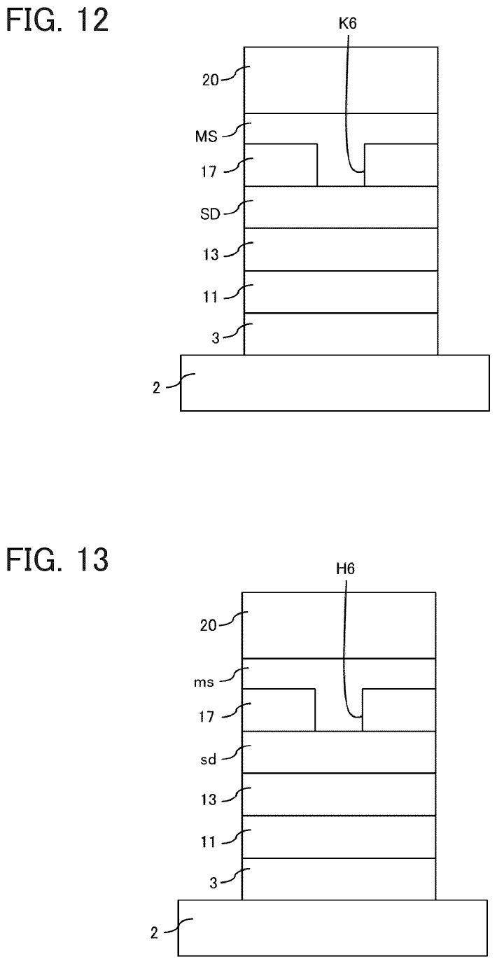

FIG. 12 is a cross-sectional view of the first effective circuit region. FIG. 13 is a cross-sectional view of the first dummy circuit region. Referring to FIG. 12, the first effective circuit region P1 may have a contact hole K6 extending through the interlayer insulating film 17 to electrically connect the conductor portion SD to the overlying wire MS (relay line W). Referring to FIG. 13, the first dummy circuit region N1 may have a through hole H6 extending through the interlayer insulating film 17 to electrically connect the dummy conductor portion sd (in the same layer as SD) to the dummy overlying wire ms (in the same layer as MS).

In addition, although neither shown nor described in detail, in either one or both of the inside of the second edge region A2 and a region between the second edge region A2 and the effective circuit region group PA is there provided a contact hole extending through the interlayer insulating film 17. Likewise, for each drive circuit region DR, in either one or both of the inside of the drive circuit region DR and a region between the drive circuit region DR and the effective circuit region group PA is there provided a contact hole extending through the interlayer insulating film 17. These contact holes are separated from the outer circumference of the effective circuit region group PA by a distance that is smaller than the dimension L of the first effective circuit region P1 in the first direction.

### Method of Manufacturing

Referring back to FIGS. 1 to 3, a description is given of a method of manufacturing the pixel circuit board PK in accordance with Embodiment 1. First of all, the undercoat film 3, the silicon semiconductor film SP, the first gate insulating film 11, the first scan signal line GN, the light-emission control line EM, the initialize signal line IL, the inorganic insulating film 13, the metal film MT, the oxide semiconductor film SZ, the second gate insulating film 15, the second scan signal line Gn, and the interlayer insulating film 17 are suitably formed and patterned on the main substrate 2. Then, the contact holes K1 to K8 and the through holes H1 to H8 are formed through the interlayer insulating film 17. Next, the overlying wire MS and the dummy overlying wire ms are formed and patterned.

The interlayer insulating film 17 is formed so as to contain a large quantity of hydrogen as an impurity. Meanwhile, the first gate insulating film 11, the inorganic insulating film 13, and the second gate insulating film 15 are formed so as to contain a small or zero quantity of hydrogen as an impurity. Alternatively, the first gate insulating film 11, the inorganic insulating film 13, and the second gate insulating film 15 may be formed so as to contain a large quantity of hydrogen as an impurity and be subjected to a process of reducing the hydrogen quantity before the oxide semiconductor film SZ is formed. In the current context, “(a film) containing a small or zero quantity of hydrogen as an impurity” means that the film discharges only a small or zero quantity of hydrogen, therefore making practically no contribution to the reduction of the oxide semiconductor film SZ, in a reduction process for the oxide semiconductor film SZ (detailed later). On the other hand, “(a film) containing a large quantity of hydrogen as an impurity” means that the film discharges a large quantity of hydrogen, therefore contributing to the reduction of the oxide semiconductor film SZ, in a reduction process for the oxide semiconductor film SZ (detailed later).

The interlayer insulating film 17 is in contact with a planned portion that will become the conductor portion SD of the oxide semiconductor film SZ, but not in contact with a planned portion that will become the channel portion SC of the oxide semiconductor film SZ.

Next, the oxide semiconductor film SZ is reduced. For example, the interlayer insulating film 17 is heated to discharge hydrogen (H) through the top and bottom surfaces of the interlayer insulating film 17 by thermal diffusion. The portion in direct contact with the bottom surface of the interlayer insulating film 17 of the oxide semiconductor film SZ has its electrical conductivity improved by the reduction by the hydrogen discharged through the bottom surface, thereby forming the conductor portion SD. On the other hand, the portion not in contact with the interlayer insulating film 17 of the oxide semiconductor film SZ is not reduced, thereby forming the channel portion SC. The hydrogen discharged through the bottom surface of the interlayer insulating film 17 then passes through the contact holes K1 to K8 and the through holes H1 to H8 (as well as through the other holes extending through the interlayer insulating film 17) and dissipates above the interlayer insulating film 17.

Subsequently, the organic insulating film 20 is sequentially formed.

### Comparative Example

A display device with no holes through the interlayer insulating film 17 in the inside of the first edge region A1 and in a region between the first edge region A1 and the effective circuit region group PA was manufactured as a display device in accordance with a comparative example. The display device in accordance with the comparative example was likely to develop bright spots on the outermost periphery on the first edge region A1 side of the display area.

### Example 1

As described above, the display device DP with the through holes H1 to H8 through the interlayer insulating film 17 in the first edge region A1 was manufactured as a display device DP in accordance with a present example of the disclosure. The display device DP in accordance with the present example of the disclosure was unlikely to develop bright spots on the outermost periphery of the display area.

Therefore, the undesirable likelihood of display defects on the outermost periphery of the display area is solved by providing the through holes H1 to H8 through the interlayer insulating film 17 outside the effective circuit region group PA.

The inventors compared the structure of the display device in accordance with the comparative example and the structure of the display device DP in accordance with the present example of the disclosure to study manufacturing processes. The inventors inferred from results of this comparative study that the bright spots that appeared in the comparative example had been caused by excessive reduction of the oxide semiconductor film SZ.

In the structure of the comparative example, no holes were provided through the interlayer insulating film 17 in the vicinity on the first edge region A1 side of the outermost periphery of the effective circuit region group PA for an effective circuit region P located on the first edge region A1 side (hereinafter, “the effective circuit region P on the first edge region A1 side”). In contrast, holes were provided through the interlayer insulating film 17 in the vicinity of all four sides for the effective circuit regions P other than the effective circuit region P on the first edge region A1 side (hereinafter, “the other effective circuit regions P”). It is therefore inferred that the hydrogen discharged through the bottom surface of the interlayer insulating film 17 in the effective circuit region P on the first edge region A1 side is less likely to dissipate above the interlayer insulating film 17 than the hydrogen discharged through the bottom surface of the interlayer insulating film 17 in the other effective circuit regions P.

From this result, it was inferred that some of the hydrogen discharged through the bottom surface of the interlayer insulating film 17 had diffused below the interlayer insulating film 17, thereby excessively reducing the oxide semiconductor film SZ, in the effective circuit region P on the first edge region A1 side in accordance with the comparative example. It was then inferred that the planned portion that would become the channel portion SC of the oxide semiconductor film SZ had been reduced, lowering the gate threshold value of the oxide semiconductor transistor.

On the other hand, in the structure in accordance with the present example of the disclosure, the through holes H1 to H8 are provided through the interlayer insulating film 17 on the first edge region A1 side for the effective circuit region P on the first edge region A1 side. Therefore, holes are provided through the interlayer insulating film 17 in the vicinity of all four sides for all the effective circuit regions P. Therefore, it is inferred that the hydrogen discharged through the bottom surface of the interlayer insulating film 17 in the effective circuit region P on the first edge region A1 side is as likely to dissipate above the interlayer insulating film 17 as the hydrogen discharged through the bottom surface of the interlayer insulating film 17 in the other effective circuit regions P.

From this result, it was inferred that no excessive reduction of the oxide semiconductor film SZ occurred in the structure in accordance with the present example of the disclosure.

### Embodiment 2

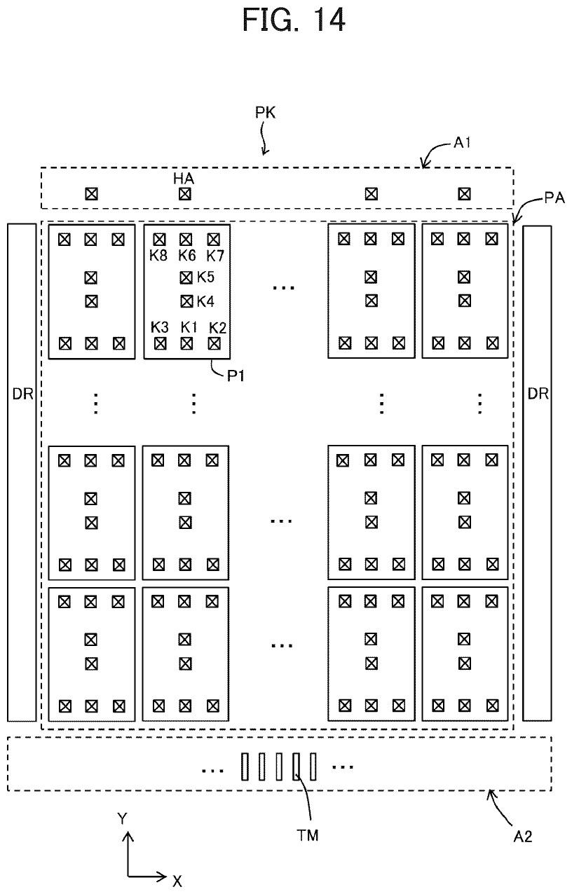

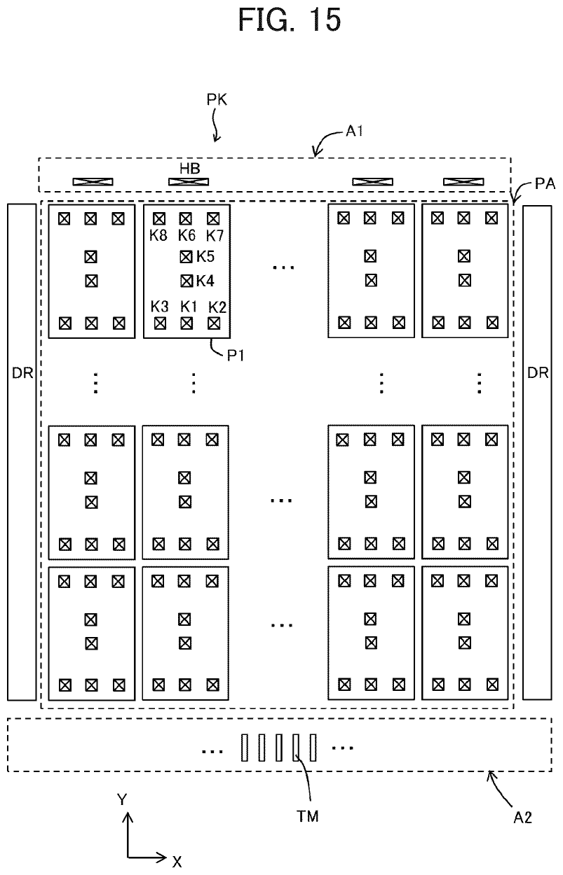

FIG. 14 is a plan view of an exemplary structure of a pixel circuit board in accordance with Embodiment 2. Referring to FIG. 14, a plurality of through holes HA may be provided without providing a dummy circuit region in the first edge region A1. The through holes HA may have any of the structures of the through holes H1 to H8. The through holes HA may be filled by an insulating film in place of a metal film. FIG. 15 is a plan view of an exemplary structure of the pixel circuit board in accordance with Embodiment 2. Referring to FIG. 15, the first edge region A1 may have through holes HB that have a greater opening area than do the contact holes (K1 to K8) in the first effective circuit region P1. The openings of the through holes HB are preferably elongated in the second direction (X-direction) of the effective circuit region group PA. The dimension of the through holes HB in the second direction may be greater than the dimension L the first effective circuit region P1 in the second direction (not shown).

### Embodiment 3

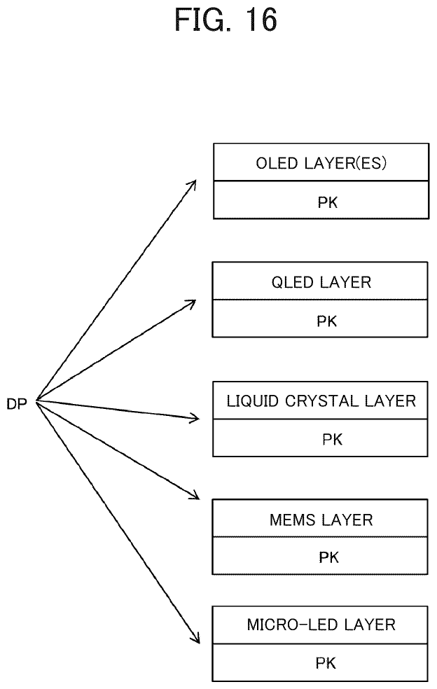

FIG. 16 is a schematic illustration of an exemplary structure of a display device in accordance with Embodiment 3. Referring to FIG. 16, the display device DP may include a pixel circuit board PK and an OLED (light-emitting diode including an organic light-emitting layer) layer (see FIG. 2). The display device DP may include a pixel circuit board PK and a QLED (light-emitting diode containing luminous quantum dots) layer. The display device DP may include a pixel circuit board PK and a liquid crystal layer. The display device DP may include a pixel circuit board PK and a MEMS layer (layer containing mechanical optical shutters). The display device DP may include a pixel circuit board PK and a micro-LED (light-emitting diode including a gallium- or like inorganic semiconductor-based light-emitting layer) layer.

The present disclosure is not limited to the description of the embodiments above and may be altered within the scope of the claims. Embodiments based on a proper combination of technical means disclosed in different embodiments are encompassed in the technical scope of the present disclosure. Furthermore, new technological features can be created by combining different technical means disclosed in the embodiments.

1. A display device comprising:
an oxide semiconductor film;
an interlayer insulating film in contact with the oxide semiconductor film; and
a pixel circuit board including an effective circuit region group configured to contribute to a display, wherein
the pixel circuit board has a first effective circuit region located on an outermost periphery of the effective circuit region group and including the oxide semiconductor film,
the first effective circuit region has a contact hole extending through the interlayer insulating film,
a through hole extending through the interlayer insulating film is provided adjacent to the first effective circuit region outside the effective circuit region group, and
the through hole has a greater opening area than does the contact hole.

2. The display device according to claim 1, wherein
the through hole and the first effective circuit region are adjacent to each other in a first direction, and
the first effective circuit region and the through hole are separated from each other in the first direction by a distance that is smaller than a dimension of the first effective circuit region in the first direction.

3. The display device according to claim 1, wherein the interlayer insulating film is provided on or above the oxide semiconductor film and contains silicon as a component element.

4. The display device according to claim 3, wherein the first effective circuit region includes an oxide semiconductor transistor with a channel being a part of the oxide semiconductor film.

5. The display device according to claim 4, wherein
the first effective circuit region includes a polysilicon transistor, and
the oxide semiconductor transistor is located closer to the through hole than to the polysilicon transistor.

6. The display device according to claim 3, wherein the interlayer insulating film contains H (hydrogen) as an impurity element.

7. The display device according to claim 1, wherein the pixel circuit board has a first edge region in which the through hole is provided.

8. The display device according to claim 1, wherein
a first dummy circuit region that does not contribute to a display is provided adjacent to the first effective circuit region outside the effective circuit region group, and
the first dummy circuit region has the through hole.

9-13. (canceled)

14. The display device according to claim 1, wherein the effective circuit region group includes a matrix of effective circuit regions including the first effective circuit region.

15. A display device comprising:
an oxide semiconductor film;
an interlayer insulating film in contact with the oxide semiconductor film; and
a pixel circuit board including an effective circuit region group configured to contribute to a display, wherein
the pixel circuit board has a first effective circuit region located on an outermost periphery of the effective circuit region group and including the oxide semiconductor film,
the first effective circuit region has a contact hole extending through the interlayer insulating film,
a through hole extending through the interlayer insulating film is provided adjacent to the first effective circuit region outside the effective circuit region group,
the pixel circuit board has a first edge region in which the through hole is provided,
the pixel circuit board has a second edge region including a plurality of terminals, and
the effective circuit region group is located between the first edge region and the second edge region.

16-20. (canceled)

21. A display device comprising:
an oxide semiconductor film;
an interlayer insulating film in contact with the oxide semiconductor film; and
a pixel circuit board including an effective circuit region group configured to contribute to a display, wherein
the pixel circuit board has a first effective circuit region located on an outermost periphery of the effective circuit region group and including the oxide semiconductor film,
the first effective circuit region has a contact hole extending through the interlayer insulating film,
a through hole extending through the interlayer insulating film is provided adjacent to the first effective circuit region outside the effective circuit region group,
the interlayer insulating film is provided on or above the oxide semiconductor film and contains silicon as a component element, and
the first effective circuit region includes an oxide semiconductor transistor with a channel being a part of the oxide semiconductor film,
the display device further comprising:
a light-emitting element layer including: an anode; a cathode; and a light-emitting layer located between the anode and the cathode; and
in the first effective circuit region, a polysilicon transistor as a drive transistor configured to control a current between the anode and the cathode, wherein
the pixel circuit board includes an initialize signal line, and
the oxide semiconductor transistor is electrically connected to a control terminal of the polysilicon transistor and to the initialize signal line.

22. The display device according to claim 1, wherein
the oxide semiconductor film contains at least one of indium, gallium, and zinc, and
the interlayer insulating film contains at least one of silicon oxide, silicon nitride, and silicon oxynitride.

23. The display device according to claim 15, wherein
the through hole and the first effective circuit region are adjacent to each other in a first direction, and
the first effective circuit region and the through hole are separated from each other in the first direction by a distance that is smaller than a dimension of the first effective circuit region in the first direction.

24. The display device according to claim 15, wherein the interlayer insulating film is provided on or above the oxide semiconductor film and contains silicon as a component element.

25. The display device according to claim 24, wherein the first effective circuit region includes an oxide semiconductor transistor with a channel being a part of the oxide semiconductor film.

26. The display device according to claim 25, wherein
the first effective circuit region includes a polysilicon transistor, and
the oxide semiconductor transistor is located closer to the through hole than to the polysilicon transistor.

27. The display device according to claim 24, wherein the interlayer insulating film contains H (hydrogen) as an impurity element.

28. The display device according to claim 15, wherein
the oxide semiconductor film contains at least one of indium, gallium, and zinc, and
the interlayer insulating film contains at least one of silicon oxide, silicon nitride, and silicon oxynitride.

29. The display device according to claim 21, wherein
the through hole and the first effective circuit region are adjacent to each other in a first direction, and
the first effective circuit region and the through hole are separated from each other in the first direction by a distance that is smaller than a dimension of the first effective circuit region in the first direction.

30. The display device according to claim 21, wherein
the oxide semiconductor film contains at least one of indium, gallium, and zinc, and
the interlayer insulating film contains at least one of silicon oxide, silicon nitride, and silicon oxynitride.
